(19) United States
(12) Patent Application Publication
(10) Pub. No.: US 2025/0167772 A1
(43) Pub. Date: May 22, 2025

(54) LOGIC CONTROL CIRCUIT, FLIP-FLOP AND PULSE GENERATING CIRCUIT

(71) Applicant: BITMAIN TECHNOLOGIES INC., Beijing (CN)

(72) Inventors: Hao YAN, Beijing (CN); An ZHAO, Beijing (CN); Lei WANG, Beijing (CN)

(21) Appl. No.: 19/023,086

(22) Filed: Jan. 15, 2025

Related U.S. Application Data
(63) Continuation of application No. PCT/CN2023/104495, filed on Jun. 30, 2023.

(30) Foreign Application Priority Data
Jul. 15, 2022 (CN) 202210833730.4

(51) Int. Cl. H03K 3/037; H03K 3/012

(52) U.S. Cl. CPC H03K 3/037; H03K 3/012

(57) ABSTRACT

A logic control circuit, a flip-flop, and a pulse generating circuit, where, the logic control circuit includes: a first MOS transistor, a second MOS transistor, a third MOS transistor, and an output circuit, a first end of the first MOS transistor is connected to a power supply, and a second end is connected to a first end of the second MOS transistor, a second end of the second MOS transistor is connected to a first end of the third MOS transistor, and a second end of the third MOS transistor is grounded. The second end of the first MOS transistor is also used to connect to a first end of an output circuit. A second end of the output circuit serves as an output terminal of the logic control circuit, and is also used to connect to a control terminal of the first MOS transistor.

### CROSS-REFERENCE TO RELATED APPLICATIONS

The present application is a continuation of International Application No. PCT/CN2023/104495, filed on Jun. 30, 2023, which claims priority to Chinese Patent Application No. 202210833730.4, filed with the China National Intellectual Property Administration on Jul. 15, 2022, and entitled “Logic control circuit, flip-flop and pulse generating circuit”. The disclosures of the aforementioned applications are hereby incorporated by reference in their entireties.

### TECHNICAL FIELD

The present application relates to the technical field of integrated circuits, and in particular to a logic control circuit, a flip-flop, and a pulse generating circuit.

### BACKGROUND

Currently, in the technical field of integrated circuits, when a circuit where the flip-flop is located implements high-speed pulses or overly narrow pulses, the output response signal has a long delay. Increasing a size of a transmission gate or an inverter in the circuit may effectively reduce the delay, but increasing the size of the transmission gate or inverter will lead to an increase in circuit power consumption. So that in the case of low-voltage circuits, the response delay will be more serious.

### SUMMARY

The main object of the present application is to provide a logic control circuit, a flip-flop and a pulse generating circuit, aiming to reduce a delay of a pulse signal output by the circuit.

In a first aspect, the present application provides a logic control circuit, where the logic control circuit includes:
a first MOS transistor, a second MOS transistor, a third MOS transistor, and an output circuit; a first end of the first MOS transistor is connected to a power supply, and a second end of the first MOS transistor is connected to a first end of the second MOS transistor, a second end of the second MOS transistor is connected to a first end of the third MOS transistor, and a second end of the third MOS transistor is grounded;
the second end of the first MOS transistor is further used to connect to a first tend of the output circuit, a second end of the output circuit serves as an output terminal of the logic control circuit, and the second end of the output circuit is further used to connect to a control terminal of the first MOS transistor, so as to control on/off of the first MOS transistor through a pulse signal at the second end of the output circuit;
a control terminal of the second MOS transistor is used to receive a first clock signal, and a control terminal of the third MOS transistor is used to receive a second clock signal, a waveform of the second clock signal is the same as that of the first clock signal, and the second clock signal is delayed by a preset duration relative to the first clock signal;
when the first MOS transistor is switched on, a voltage signal at the second end of the first MOS transistor is in a high level, and when level of the first clock signal is different from that of the second clock signal, the second MOS transistor or the third MOS transistor is switched off, to keep the second end of the first MOS transistor in a high level;
when the first MOS transistor is switched off, and when the level of the first clock signal is the same as that of the second clock signal, the second MOS transistor and the third MOS transistor are both switched on, so as to set the voltage at the second end of the first MOS transistor to a low level.

In a second aspect, the present application further provides another logic control circuit, where the logic control circuit includes:
a first MOS transistor, a second MOS transistor, a third MOS transistor, and an output circuit; a first end of the first MOS transistor is used to connect to a power supply, and a second end of the first MOS transistor is connected to a first end of the second MOS transistor, a second end of the second MOS transistor is connected to a first end of the third MOS transistor, and a second end of the third MOS transistor is grounded;
the second end of the second MOS transistor is further connected to a first end of the output circuit, a second end of the output circuit serves as an output terminal of the logic control circuit, and the second end of the output circuit is further connected to a control terminal of the third MOS transistor, so as to control the on/off of the third MOS transistor through a pulse signal at the second end of the output circuit;
the first MOS transistor further includes a control terminal for receiving a first clock signal, and the second MOS transistor further includes a control terminal for receiving a second clock signal, a waveform of the second clock signal is the same as that of the first clock signal, and the second clock signal is delayed by a preset duration relative to the first clock signal;
when the third MOS transistor is turned off, and when the level of the first clock signal is the same as that of the second clock signal, the first MOS transistor and the second MOS transistor are both switched on, so as to set the second end of the first MOS transistor to a high level;
when the level of the first clock signal is different from that of the second clock signal, the first MOS transistor or the second MOS transistor are switched off, and when the third MOS transistor is switched on, the second end of the first MOS transistor is set to a low level.

In a third aspect, the application also provides a flip-flop, and where the flip-flop includes:
the logic control circuit according to the above first aspect; or the logic control circuit according to the above second aspect.

In a fourth aspect, the application further provides a pulse generating circuit, where the pulse generating circuit includes:
the logic control circuit according to the above first aspect;
a first delay inverting circuit, where one end of the first delay inverting circuit is used to receive the first clock signal, and the other end is connected to the control terminal of the third MOS transistor, so as to input the generated second clock signal to the control terminal of the third MOS transistor, delay the second clock signal by a first preset duration relative to the first clock signal.

In a fifth aspect, the application further provides a pulse generating circuit, and where the pulse generating circuit includes:
the logic control circuit according to the above second aspect;
a first delay inverting circuit, where one end of the first delay inverting circuit is used to receive the first clock signal, and the other end is connected to a control terminal of the second MOS transistor;
a second delay inverting circuit, where the second delay inverting circuit is connected between the second end of the second MOS transistor and the control terminal of the third MOS transistor; the second delay inverting circuit is used to perform inversion processing and delay processing on a pulse signal at the second end of the second MOS transistor, so that the pulse signal received by the control terminal of the third MOS transistor is delayed by a preset duration relative to the pulse signal at the second end of the second MOS transistor.

In a sixth aspect, the application further provides a pulse generating circuit, and where the pulse generating circuit includes:
the logic control circuit according to the above second aspect;
a delay inverting circuit, where one end of the delay inverting circuit is used to receive the first clock signal, and the other end is connected to a control terminal of the second MOS transistor;
a delay circuit, where the delay circuit is connected between the second end of the second MOS transistor and the control terminal of the third MOS transistor; the delay circuit is used to perform delay processing on the voltage signal output from the second end of the second MOS transistor, so that the pulse signal received by the control terminal of the third MOS transistor is delayed by a preset duration relative to the pulse signal at the second end of the second MOS transistor.

The present application provides a logic control circuit, a flip-flop and a pulse generating circuit. The present application reduces the number of electronic components in the circuit to simplify a circuit design by working together with multiple MOS transistors, and may reduce the delay of the response signal under low voltage working conditions.

### BRIEF DESCRIPTION OF DRAWINGS

In order to more clearly illustrate the technical solutions of the embodiments of the present application, the drawings required for use in the description of the embodiments will be briefly introduced below. Obviously, the drawings described below are some embodiments of the present application. For ordinary skilled person in the field, other drawings may be obtained based on these drawings without paying any creative work.

FIG. 1 is a schematic diagram of a logic control circuit provided by an embodiment of the present application.

FIG. 2 is a schematic diagram of a clock signal of a logic control circuit provided by an embodiment of the present application.

FIG. 3 is a schematic diagram of a logic control circuit provided by another embodiment of the present application.

FIG. 4 is a schematic diagram of a logic control circuit provided by an embodiment of the present application.

FIG. 5 is a schematic diagram of a logic control circuit provided by another embodiment of the present application.

FIG. 6 is a schematic diagram of a logic control circuit provided by another embodiment of the present application.

FIG. 7 is a schematic diagram of a logic control circuit provided by yet another embodiment of the present application.

FIG. 8 is a schematic diagram of a logic control circuit provided by another embodiment of the present application.

FIG. 9 is a schematic diagram of a logic control circuit provided by yet another embodiment of the present application.

FIG. 10 is a schematic diagram of a logic control circuit provided by still another embodiment of the present application.

FIG. 11 is a schematic diagram of a logic control circuit provided by an embodiment of the present application.

FIG. 12 is a schematic diagram of a pulse generating circuit provided by an embodiment of the present application.

FIG. 13 is a schematic diagram of a pulse generating circuit provided by another embodiment of the present application.

FIG. 14 is a timing diagram corresponding to the embodiment of FIG. 13.

FIG. 15 is a schematic diagram of a pulse generating circuit provided by another embodiment of the present application.

The achievement of the purpose, functional features and advantages of the application will be further explained in conjunction with embodiments and with reference to the drawings.

### REFERENCE NUMBERS

Q1: First MOS transistor; Q2: Second MOS transistor; Q3: Third MOS transistor;

10: Output circuit; Q4: Fourth MOS transistor; M1: First inverter;

M2: NAND gate; Q5: Fifth MOS transistor; M3: Second inverter;

M4: Inverter; Q6: Sixth MOS transistor; Q7: Seventh MOS transistor;

Q8: Eighth MOS transistor; T1: First delay inverting circuit; T2: Second delay inverting circuit;

T3: Delay inverting circuit; T4: Delay circuit; CLK: First clock signal;

CLKND: Second clock signal.

### DESCRIPTION OF EMBODIMENTS

The technical solutions in the embodiments of the present application will be clearly and completely described below in conjunction with the drawings in the embodiments of the present application. Obviously, the described embodiments are only part of the embodiments of the present application, rather than all of the embodiments. Based on the embodiments in the application, all other embodiments obtained by ordinary skilled person in the art without making any creative work shall fall within the protection scope of the present application.

The flowcharts shown in the drawings are only examples for illustration and do not necessarily include all contents and operations/steps, nor do they necessarily have to be executed in the order described. For example, some operations/steps may be decomposed, combined or partially merged, so the actual execution order may change according to actual circumstances.

Some implementations of the present application are described in detail below in conjunction with the drawings. In the absence of conflict, the following embodiments and features in the embodiments may be combined with each other.

In the prior art, some pulse generating circuits may include a D-type flip-flop, and by inputting a clock signal into the D-type flip-flop, the D-type flip-flop generate a corresponding pulse signal for output by responding to the input clock signal. However, due to the large number of logic gate electronic components in the D-type flip-flop, there is a certain delay in generating the pulse signal in response to the clock signal. If the size or area of the logic gate electronic components in the D-type flip-flop is increased, the delay may be reduced to some extent, but this also increases the power consumption of the circuit, and it is not convenient for the design of integrated circuits. In addition, under low voltage operating conditions, the loss and delay in the circuit will become more prominent.

In order to simplify the circuit design and make it suitable for low voltage working environments, the present application proposes a logic control circuit, a flip-flop, and a pulse generating circuit.

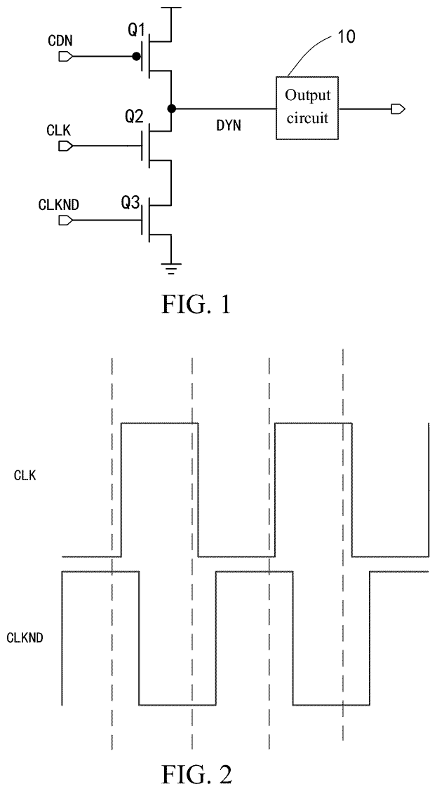

Please refer to FIG. 1, FIG. 1 is a schematic diagram of a logic control circuit provided by an embodiment of the present application.

As shown in FIG. 1, the logic control circuit includes: a first MOS transistor Q1, a second MOS transistor Q2, a third MOS transistor Q3, and an output circuit 10. A first end of the first MOS transistor Q1 is connected to a power supply, and a second end of the first MOS transistor Q1 is connected to a first end of the second MOS transistor Q2; a second end of the second MOS transistor Q2 is connected to a first end of the third MOS transistor Q3, and a second end of the third MOS transistor Q3 is grounded.

The second end of the first MOS transistor Q1 is also used to connect to a first end of the output circuit 10, a second end of the output circuit 10 serves as an output terminal of the logic control circuit, and the second end of the output circuit 10 is further used to connect to a control terminal of the first MOS transistor Q1. It may be understood that the second end of the output circuit 10 will output a pulse signal, so that on/off of the first MOS transistor Q1 may be controlled by the pulse signal output from the second end of the output circuit 10. For the convenience of expression, the pulse signal received by the first MOS transistor Q1 is referred to as a CDN signal hereinafter. It may be understood that the CDN signal may be the same as the pulse signal output from the second end of the output circuit 10, or the CDN signal may be obtained by performing preset processing on the pulse signal output from the second end of the output circuit 10.

A control terminal of the second MOS transistor Q2 is used to receive the first clock signal CLK, and a control terminal of the third MOS transistor Q3 is used to receive the second clock signal CLKND. As shown in FIG. 2. FIG. 2 is a schematic diagram of a clock signal of a logic control circuit provided by an embodiment of the present application. It may be understood that a waveform of the second clock signal CLKND is the same as that of the first clock signal CLK, and the second clock signal CLKND is delayed by a preset duration relative to the first clock signal CLK.

The first clock signal CLK and the second clock signal CLKND have an in-phase state and an anti-phase state. The in-phase state is used to indicate that level of the first clock signal CLK is the same as the level of the second clock signal CLKND, that is, the first clock signal CLK and the second clock signal CLKND are both high level signals or low level signals. The anti-phase state is used to indicate that the level of the first clock signal CLK is opposite to the level of the second clock signal CLKND. It may be understood that in each cycle, there are two in-phase states, and the duration of each in-phase state is a preset duration.

Exemplarily, the first clock signal CLK and the second clock signal CLKND may be provided by a clock circuit connected to the logic control circuit. In some implementations, it may be understood that the logic control circuit may be connected to a first clock circuit and a second clock circuit to receive the first clock signal CLK transmitted by the first clock circuit and the second clock signal CLKND transmitted by the second clock circuit. In some other implementations, the logic control circuit is connected to one clock circuit to receive the clock signal transmitted by the same clock circuit.

In some embodiments, as shown in FIG. 1, the first MOS transistor Q1 is a PMOS transistor, and the second MOS transistor Q2 and the third MOS transistor Q3 are both NMOS transistors. The pulse signal output from the second end of the output circuit 10 is the same as the voltage signal at the second end of the first MOS transistor Q1. For the convenience of description, a data node DYN is introduced. The data node DYN is located at the second end of the first MOS transistor Q1 and is used to indicate a level signal at the second end of the first MOS transistor Q1.

It may be understood that in the logic control circuit, a state when the data node DYN of the logic control circuit is in a low level may be regarded as the initial state. It may be understood that, at this time, the pulse signal output from the second end of the output circuit 10 is a low level pulse signal, and this pulse signal is transmitted to the control terminal of the first MOS transistor Q1, causing the first MOS transistor Q1 to switch on. Thus, the power supply connected to the first end of the first MOS transistor Q1 may apply a voltage to the second end of the first MOS transistor Q1 through the first MOS transistor Q1, setting the data node DYN to a high level. When the level of the first clock signal CLK is different from that of the second clock signal CLKND, the second MOS transistor Q2 or the third MOS transistor Q3 is switched off, enabling the data node DYN to maintain a high level state.

At this moment, the data node DYN of the logic control circuit is in a high level state. When the pulse signal at the second end of the output circuit 10 is also a high level signal and is transmitted to the control terminal of the first MOS transistor Q1, the first MOS transistor Q1 is switched off, and the data node DYN is still in a high level state. However, when the levels of the first clock signal CLK and the second clock signal CLKND are the same, the second MOS transistor Q2 and the third MOS transistor Q3 are both switched on, and the data node DYN is set to a low level.

Specifically, when the second transistor and third MOS transistor Q3 are NMOS transistors, and the first clock signal CLK is a low level signal, the second clock signal CLKND is a high level signal. At this time, the second MOS transistor Q2 is switched off and the third MOS transistor Q3 is switched on, and the data node DYN is still in a high level state. When a rising edge of the first clock signal CLK arrives and the first clock signal CLK is set to a high level signal, since the second clock signal CLKND is delayed by a preset duration relative to the first clock signal CLK, the first clock signal CLK and the second clock signal CLKND enter the in-phase state. In this state, the second MOS transistor Q2 and the third MOS transistor Q3 are both switched on, and the data node DYN may be regarded as being grounded through the second MOS transistor Q2 and the third MOS transistor Q3, to set the data node DYN to a low level. As a result, the second end of the output circuit 10 outputs a low level pulse signal. After a preset duration, the first clock signal CLK and the second clock signal CLKND enter the anti-phase state, and the logic control circuit returns to the initial state and repeats a step of transmitting the low level pulse signal to the control terminal of the first MOS transistor Q1, which will not be repeated here.

It may be understood that controlling the on/off of the second transistor and third MOS transistor Q3 and the on/off state of the first MOS transistor Q1 by a periodic clock signal, the level state of the data node DYN in the logic control circuit may be controlled. Thus, a corresponding pulse signal is output from the second end of the output circuit 10, achieving the purpose of generating a pulse signal.

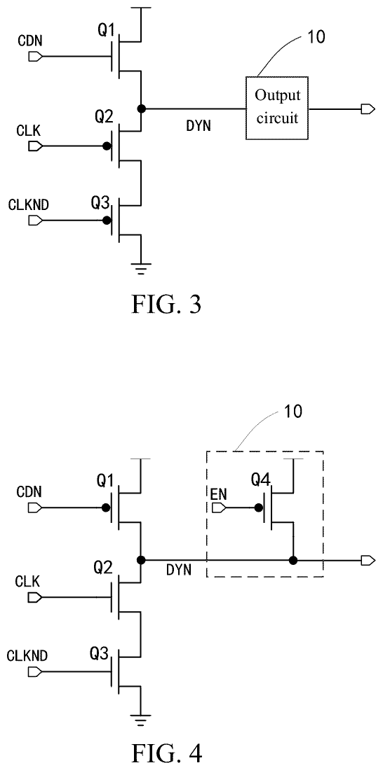

Please refer to FIG. 3, FIG. 3 is a schematic diagram of a logic control circuit provided by another embodiment of the present application.

In some other embodiments, as shown in FIG. 3, the first MOS transistor Q1 is a NMOS transistor, the second MOS transistor Q2 and the third MOS transistor Q3 are both PMOS transistors.

Exemplarily, since the first MOS transistor Q1 is a NMOS transistor, when the data node DYN is in a low level, if the second end of the output circuit 10 outputs a low level pulse signal and transmits it to the control terminal of the first MOS transistor Q1, the first MOS transistor Q1 will not be switched on, and thus the data node DYN cannot be set to a high level. Therefore, it is necessary to perform inversion processing on the level of the data node DYN or on the pulse signal output from the second end of the output circuit 10 to ensure that the CDN signal received by the control terminal of the first MOS transistor Q1 is inverted with the level signal of the data node DYN.

It may be considered that in the output circuit 10, the inversion processing is performed on the signal of the data node DYN, so that the pulse signal output from the second end of the output circuit 10 is inverted with the level signal of the data node DYN.

Similarly, the state when the data node DYN of the logic control circuit is in a low level is regarded as the initial state. At this time, the pulse signal output from the second end of the output circuit 10 is a high level pulse signal, and this pulse signal is transmitted to the control terminal of the first MOS transistor Q1, to make the first MOS transistor Q1 to switch on. Thus, the power supply connected to the first end of the first MOS transistor Q1 may apply a voltage to the second end of the first MOS transistor Q1 through the first MOS transistor Q1, to set the data node DYN to a high level. When the level of the first clock signal CLK is different from that of the second clock signal CLKND, the second MOS transistor Q2 or the third MOS transistor Q3 is switched off, enabling the data node DYN to maintain a high level state.

At this time, the data node DYN of the logic control circuit is in a high level state. When the pulse signal of the output circuit 10 becomes a low level signal and is transmitted to the control terminal of the first MOS transistor Q1, the first MOS transistor Q1 is switched off, and the data node DYN is still in a high level state. However, when the level of the first clock signal CLK is the same as that of the second clock signal CLKND, the second MOS transistor Q2 and the third MOS transistor Q3 are both switched on, and the data node DYN is set to a low level.

Specifically, when the second transistor and third MOS transistor Q3 are PMOS transistors, and the first clock signal CLK is a high level signal and the second clock signal CLKND is a low level signal, the second MOS transistor Q2 is switched off and the third MOS transistor Q3 is switched on, and the data node DYN is still in a high level state. When a falling edge of the first clock signal CLK arrives and the first clock signal CLK is set to a low level signal, the first clock signal CLK and the second clock signal CLKND enter the in-phase state. In this state, the second MOS transistor Q2 and the third MOS transistor Q3 are both switched on, and the data node DYN may be regarded as being grounded through the second MOS transistor Q2 and the third MOS transistor Q3, to set the data node DYN to a low level. After a preset duration, the first clock signal CLK and the second clock signal CLKND enter the anti-phase state, and the logic control circuit returns to the initial state and repeats the step of transmitting the high level pulse signal to the control terminal of the first MOS transistor Q1, which will not be repeated here.

Please refer to FIG. 4 in conjunction with FIG. 1. FIG. 4 is a schematic diagram of a logic control circuit provided by an embodiment of the present application.

In some implementations, as shown in FIG. 4, the output circuit 10 includes a fourth MOS transistor Q4. A control terminal of the fourth MOS transistor Q4 serves as the control terminal of the output circuit 10 and is used to receive an enable signal EN. A first end of the fourth MOS transistor Q4 is connected to the power supply, and a second end of the fourth MOS transistor Q4 is connected to the second end of the first MOS transistor Q1.

It may be understood that the fourth MOS transistor Q4 may be connected to the same power supply as the first MOS transistor Q1.

The fourth MOS transistor Q4 is used to control the pulse signal output from the second end of the output circuit 10 according to the enable signal. It may be understood that when the enable signal EN is used to indicate that there is signal output, the output circuit 10 may generate a corresponding pulse signal based on the state of the data node DYN. When the enable signal is used to indicate that there is no signal output, the fourth MOS transistor Q4 controls the second end of the output circuit 10 to have no pulse signal output. At this time, the second transistor and third MOS transistor Q3 may still receive the clock signal, but the second end of the output circuit 10 has no pulse signal output.

For example, when the enable signal EN is a high level signal, it indicates that there is signal output; when the enable signal EN is a low level signal, it indicates that there is no signal output.

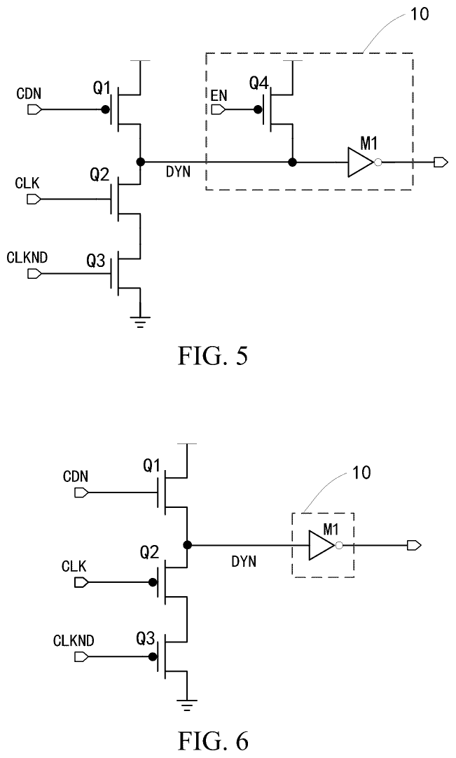

Please refer to FIG. 5 in conjunction with FIG. 1. FIG. 5 is a schematic diagram of a logic control circuit provided by another embodiment of the present application.

In some implementations, as shown in FIG. 5, when the first MOS transistor Q1 is a PMOS transistor, the second MOS transistor Q2 and the third MOS transistor Q3 are NMOS transistors, the output circuit 10 further includes a first inverter M1. An input terminal of the first inverter M1 is connected to the second end of the first MOS transistor Q1, and an output terminal of the first inverter M1 serves as the second end of the output circuit 10.

It may be understood that setting the first inverter M1 in the output circuit 10 may perform the inversion processing on the level signal of the data node DYN connected to the input terminal of the first inverter M1, so that the pulse signal output from the second end of the output circuit 10 is inverted with the level signal of the data node DYN.

When the first MOS transistor Q1 is a PMOS transistor, and the second transistor and third MOS transistor Q3 are NMOS transistors, the control terminal of the first MOS transistor Q1 needs to receive a low level signal to make the first MOS transistor Q1 to switch on. If the data node DYN is a low level and the pulse signal output from the second end of the output circuit 10 is a high level, the first MOS transistor Q1 is not switched on, the data node DYN remains in a low level state, and the circuit cannot operate. Therefore, it is necessary to perform the inversion processing on the pulse signal output from the second end of the output circuit 10 to obtain an inverting signal of the pulse signal output from the second end of the output circuit 10, so as to perform two inversion processing on the signal of the data node DYN, thereby ensuring that the signal received by the control terminal of the first MOS transistor Q1 is in-phase with the signal of the data node DYN, so that when the data node DYN is a low level, the first MOS transistor Q1 may be switched on and set the data node DYN to a high level, and then perform the steps described above, which will not be repeated here.

It may be understood that a stable pulse signal may be obtained by performing two inversion processing to avoid logic errors in the first MOS transistor Q1 or the data node DYN in the circuit.

It may be understood that the inversion processing of the pulse signal output from the second end of the output circuit 10 may be performed in the circuit connected to the logic control circuit and using the inverter or other devices capable of performing the inversion processing, so that the pulse signal received by the control terminal of the first MOS transistor Q1 is inverted with the pulse signal output from the second end of the output circuit 10.

Exemplarily, the embodiment provided in FIG. 5 may be combined with the embodiment provided in FIG. 4.

Please refer to FIG. 6 in conjunction with FIG. 3. FIG. 6 is a schematic diagram of a logic control circuit provided by another embodiment of the present application.

In some other implementations, as shown in FIG. 6, when the first MOS transistor Q1 is a NMOS transistor, and the second transistor and third MOS transistor Q3 are PMOS transistors, the output circuit 10 further includes a first inverter M1. The input terminal of the first inverter M1 is connected to the second end of the first MOS transistor Q1, and the output terminal of the first inverter M1 serves as the second end of the output circuit 10.

It may be understood that when the first MOS transistor Q1 is a NMOS transistor and the second transistor and third MOS transistor Q3 are PMOS transistors, the control terminal of the first MOS transistor Q1 needs to receive a high level signal to make the first MOS transistor Q1 to switch on. If the data node DYN is a low level, and the first inverter M1 in the output circuit 10 performs inversion processing, a high level pulse signal is output from the second end of the output circuit 10. The first MOS transistor Q1 is switched on after receiving the high level pulse signal, the data node DYN is set to a high level, and the previous steps are repeated, which will not be repeated here.

Exemplarily, the embodiment provided in FIG. 6 may be combined with the embodiment provided in FIG. 4.

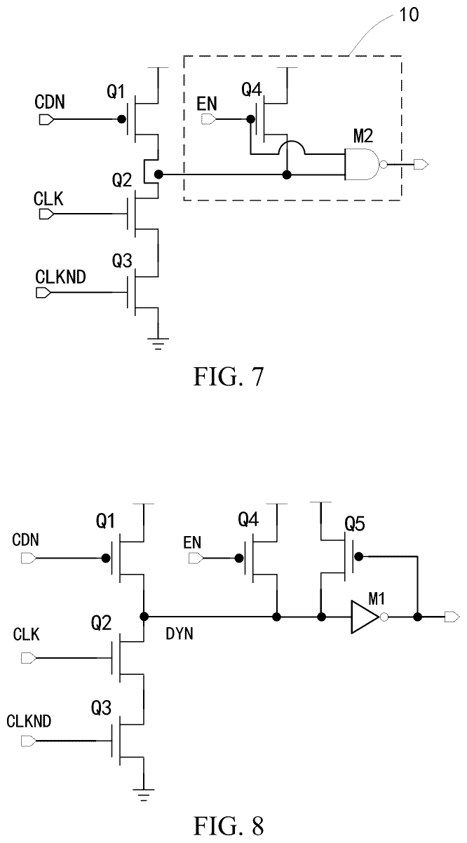

Please refer to FIG. 7 in conjunction with FIG. 4. FIG. 7 is a schematic diagram of a logic control circuit provided by yet another embodiment of the present application.

In some implementations, the first MOS transistor Q1 is a NMOS transistor, and the second MOS transistor, third MOS transistor, and fourth MOS transistor Q4 are PMOS transistors. The output circuit 10 further includes a NAND gate M2. A first signal input terminal of the NAND gate M2 is connected to the control terminal of the fourth MOS transistor Q4, a second signal input terminal of the NAND gate M2 is connected to the second end of the fourth MOS transistor Q4, and an output terminal of the NAND gate M2 serves as the second end of the output circuit 10.

It may be understood that when the data node DYN or the enable signal EN is a low level, the second end of the output circuit 10 outputs a high level pulse signal, causing the first MOS transistor Q1 to switch on and setting the data node DYN to a high level. When the data node DYN and the enable signal EN are both a high level, the second end of the output circuit 10 outputs a low level pulse signal, causing the first MOS transistor Q1 to switch off and the data node DYN to remain in a high level state.

When the second MOS transistor Q2 and the third MOS transistor Q3 are both switched on, the data node DYN is set to a low level again. For the specific circuit operation steps, please refer to the logic control circuit corresponding to FIG. 3, which will not be repeated here.

In some other implementations, the first MOS transistor Q1 is a PMOS transistor, and the second MOS transistor, third MOS transistor, and fourth MOS transistor Q4 are NMOS transistors. The output circuit 10 further includes a NAND gate M2. A first signal input terminal of the NAND gate M2 is connected to the control terminal of the fourth MOS transistor Q4, a second signal input terminal of the NAND gate M2 is connected to the second end of the fourth MOS transistor Q4, and an output terminal of the NAND gate M2 serves as the second end of the output circuit 10.

Exemplarily, when the data node DYN or the enable signal is a low level, the second end of the output circuit 10 outputs a high level pulse signal, and it needs to perform the inversion processing on the pulse signal output from the second end of the output circuit 10 to make the first MOS transistor Q1 to switch on and set the data node DYN to a high level.

When the data node DYN and the enable signal are both a high level, the second end of the output circuit 10 outputs a low level pulse signal, the first MOS transistor Q1 is switched off, and the data node DYN is still in a high level.

When the second MOS transistor Q2 and the third MOS transistor Q3 are both switched on, the data node DYN is set to a low level. For the specific circuit operation steps, please refer to the logic control circuit corresponding to FIG. 1, which will not be repeated here.

Please refer to FIG. 8 in conjunction with FIG. 5. FIG. 8 is a schematic diagram of a logic control circuit provided by another embodiment of the present application.

In some embodiments, the logic control circuit further includes a fifth MOS transistor Q5. A control terminal of the fifth MOS transistor Q5 is connected to the output terminal of the first inverter M1, a first end of the fifth MOS transistor Q5 is used to connect to the power supply, and a second end of the fifth MOS transistor Q5 is connected to the input terminal of the first inverter M1.

Exemplarily, by connecting the fifth MOS transistor Q5, signal stability in the logic control circuit may be maintained. The specific operation steps of the logic control circuit are the same as those provided in the previous embodiments, which will not be repeated here.

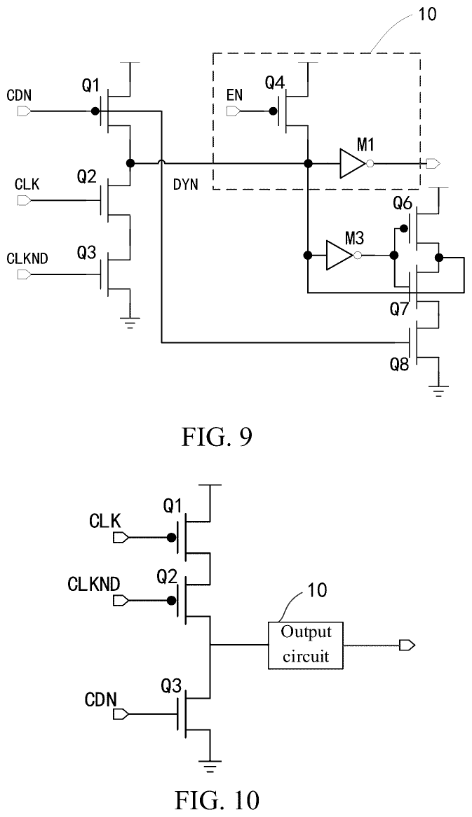

Please refer to FIG. 9 in conjunction with FIG. 1, FIG. 9 is a schematic diagram of a logic control circuit provided by yet another embodiment of the present application.

In some embodiments, the logic control circuit further includes: a second inverter M3, a sixth MOS transistor Q6, a seventh MOS transistor Q7, and an eighth MOS transistor Q8. Where, the sixth MOS transistor Q6 is a PMOS transistor, and the seventh transistor and eighth MOS transistor Q8 are NMOS transistors. A first end of the sixth MOS transistor Q6 is used to connect to the power supply, and a second end of the sixth MOS transistor Q6 is connected to a first end of the seventh MOS transistor Q7. A second end of the seventh MOS transistor Q7 is connected to a first end of the eighth MOS transistor Q8, and a second end of the eighth MOS transistor Q8 is grounded.

The control terminals of the sixth MOS transistor Q6 and the seventh MOS transistor Q7 are both connected to the output terminal of the second inverter M3. The input terminal of the second inverter M3 is connected to the first end of the output circuit 10, and the input terminal of the second inverter M3 is also connected to the second end of the sixth MOS transistor Q6. The control terminal of the eighth MOS transistor Q8 is connected to the control terminal of the first MOS transistor Q1.

It may be understood that when the data node DYN is a low level, the inversion processing is performed through the second inverter M3, and a high level signal is output from the output terminal of the second inverter M3 to control the sixth MOS transistor Q6 to switch off and the seventh MOS transistor Q7 to switch on. When the control terminal of the first MOS transistor Q1 receives a high level pulse signal, the eighth MOS transistor Q8 is switched on, and the second end of the sixth MOS transistor Q6 may be regarded as grounded and set to a low level.

When the control terminal of the first MOS transistor Q1 receives a low level pulse signal, the first MOS transistor Q1 is switched on, the eighth MOS transistor Q8 is switched off, and the data node DYN is set to a high level. Through performing the inversion processing on the second inverter M3, a low level signal is output from the output terminal of the second inverter M3, to make the sixth MOS transistor Q6 to switch on, the seventh MOS transistor Q7 to switch off, and the second end of the sixth MOS transistor Q6 is set to a high level. That is, the data may be latched in the second end of the sixth MOS transistor Q6. When the data node DYN is set to a low level, the second end of the sixth MOS transistor Q6 is also set to a low level to accomplish the purpose of data clearing.

It may be understood that through the second inverter M3, the sixth transistor, seventh transistor, and eighth MOS transistor Q8 may perform latching processing on data and maintain signal stability.

Please refer to FIG. 10, FIG. 10 is a schematic diagram of a logic control circuit provided by still another embodiment of the present application.

As shown in FIG. 10, the logic control circuit includes: a first MOS transistor Q1, a second MOS transistor Q2, a third MOS transistor Q3, and an output circuit 10. A first end of the first MOS transistor Q1 is used to connect to the power supply, and a second end of the first MOS transistor Q1 is connected to a first end of the second MOS transistor Q2. A second end of the second MOS transistor Q2 is connected to a first end of the third MOS transistor Q3, and a second end of the third MOS transistor Q3 is grounded.

The second end of the second MOS transistor Q2 is also connected to a first end of the output circuit 10. A second end of the output circuit 10 serves as an output terminal of the logic control circuit, and the second end of the output circuit 10 is also connected to a control terminal of the third MOS transistor Q3 to control the on/off of the third MOS transistor Q3 through the pulse signal at the second end of the output circuit 10.

The first MOS transistor Q1 further includes a control terminal for receiving a first clock signal CLK, and the second MOS transistor Q2 further includes a control terminal for receiving a second clock signal CLKND. The waveform of the second clock signal CLKND is the same waveform as that of the first clock signal CLK and is delayed by a preset duration relative to the first clock signal CLK. When the third MOS transistor Q3 is switched off, and when the level of the first clock signal CLK is the same as the level of the second clock signal CLKND, the first MOS transistor Q1 and the second MOS transistor Q2 are both switched on to set the second end of the first MOS transistor Q1 to a high level. When the level of the first clock signal CLK is different from the level of the second clock signal CLKND, the first MOS transistor Q1 or the second MOS transistor Q2 is switched off; and when the third MOS transistor Q3 is switched on, the second end of the first MOS transistor Q1 is set to a low level.

Exemplarily, the second end of the second MOS transistor Q2 serves as a data node DYN, and when the data node DYN is a low level, the first MOS transistor Q1 and the second MOS transistor Q2 need to be switched on simultaneously to set the data node DYN to a high level.

Exemplarily, the control terminal of the first MOS transistor Q1 receives the first clock signal CLK, and the control terminal of the second MOS transistor Q2 receives the second clock signal CLKND, where there are an in-phase state and an anti-phase state for the first clock signal CLK and the second clock signal CLKND, the in-phase state is used to indicate that the level of the first clock signal CLK is the same as the level of the second clock signal CLKND, that is, the first clock signal CLK and the second clock signal CLKND are both high level signals or low level signals; the anti-phase state is used to indicate that the level of the first clock signal CLK is opposite to the level of the second clock signal CLKND. It may be understood that in each cycle, there are two in-phase states, and the duration of each in-phase state is a preset duration.

Exemplarily, when the third MOS transistor Q3 is switched on, the data node DYN may be set to a low level.

In some implementations, the first transistor and second MOS transistor Q2 are PMOS transistors, and the third MOS transistor Q3 is a NMOS transistor. When the data node DYN is a low level, and when the falling edge of the first clock signal CLK arrives and the first clock signal CLK is set to a low level signal, the first clock signal CLK and the second clock signal CLKND are in the in-phase state, the first MOS transistor Q1 and the second MOS transistor Q2 are both switched on, the data node DYN is set to a high level. After a preset duration, the first clock signal CLK and the second clock signal CLKND are in the anti-phase state, either the first MOS transistor Q1 or the second MOS transistor Q2 is switched off, and the data node DYN is still a high level.

When the control terminal of the third MOS transistor Q3 receives a high level pulse signal, the third MOS transistor Q3 is controlled to switch on, to set the data node DYN to a low level, and after the next falling edge of the first clock signal CLK arrives, the above-mentioned steps are repeated.

It may be understood that the data node DYN is connected to the first end of the output circuit 10, and the second end of the output circuit 10 is connected to the control terminal of the third MOS transistor Q3. The pulse signal at the output terminal of the output circuit 10 may control the on/off of the third MOS transistor Q3. Therefore, in order to avoid frequency of the level change of the data node DYN being too fast, delay processing may be performed on the pulse signal at the output terminal of the output circuit 10, so that the third MOS transistor Q3 receives the pulse signal from the output terminal of the output circuit 10 after a second preset duration.

In some other implementations, the first MOS transistor and second MOS transistor Q2 are NMOS transistors, and the third MOS transistor Q3 is a PMOS transistor.

When the data node DYN is a low level, and when the rising edge of the first clock signal CLK arrives and the first clock signal CLK is set to a high level signal, the first clock signal CLK and the second clock signal CLKND are in the in-phase state, the first MOS transistor Q1 and the second MOS transistor Q2 are both switched on, the data node DYN is set to a high level; after a preset duration, the first clock signal CLK and the second clock signal CLKND are in the anti-phase state, either the first MOS transistor Q1 or the second MOS transistor Q2 is switched off, and the data node DYN is still a high level.

When the control terminal of the third MOS transistor Q3 receives a low level pulse signal, the third MOS transistor Q3 is controlled to switch on, the data node DYN is set to a low level, and after the next rising edge of the first clock signal CLK arrives, the above-mentioned steps are repeated.

It may be understood that in this case, if the pulse signal output from the second end of the output circuit 10 is in-phase with the level signal of the data node DYN, and the data node DYN is a high level, the third MOS transistor Q3 receives a high level pulse signal and is in the off state, so that the data node DYN cannot be set to a low level. Therefore, at this time, it needs to perform the inversion processing on the level signal of the data node DYN, so that the level signal of the data node DYN is inverted with respect to the pulse signal received by the control terminal of the third MOS transistor Q3. For example, the inversion processing may be performed in the output circuit 10, or an electronic component for the inversion processing, such as an inverter, may be connected between the control terminal of the third MOS transistor Q3 and the second end of the output circuit 10.

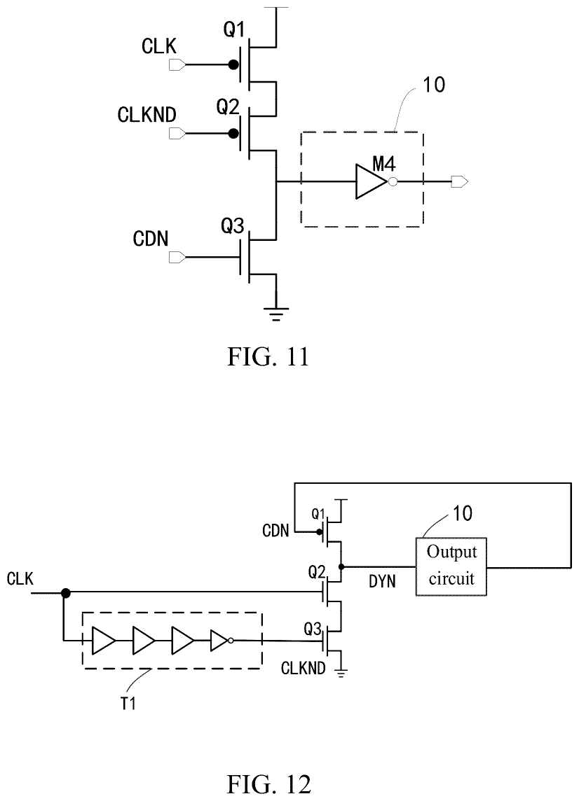

Please refer to FIG. 11 in conjunction with FIG. 10, FIG. 11 is a schematic diagram of a logic control circuit provided by an embodiment of the present application. The output circuit 10 includes an inverter M4. An input terminal of the inverter M4 is connected to the second end of the second MOS transistor Q2, and an output terminal of the inverter M4 serves as the second end of the output circuit 10.

It may be understood that when the first MOS transistor and second MOS transistor Q2 are NMOS transistors and the third MOS transistor Q3 is a PMOS transistor, the second end of the output circuit 10 is connected to the control terminal of the third MOS transistor Q3, so that when the data node DYN is a high level, the output terminal of the output circuit 10 outputs a low level pulse signal, and this low level pulse signal is transmitted to the control terminal of the third MOS transistor Q3, causing the third MOS transistor Q3 to switch on, thus the data node DYN is set to a low level. The remaining steps are the same as those provided in the previous embodiments and will not be repeated here.

When the first MOS transistor and second MOS transistor Q2 are PMOS transistors and the third MOS transistor Q3 is a NMOS transistor, if the data node DYN is a high level, the second end of the output circuit 10 outputs a low level pulse signal, it needs to perform the inversion processing on the pulse signal, and the processed pulse signal is transmitted to the control terminal of the third MOS transistor Q3, causing the third MOS transistor Q3 to switch on and the data node DYN is set to a low level. The remaining steps are the same as those provided in the previous embodiments and will not be repeated here.

The present application also provides a flip-flop, where the flip-flop includes the logic control circuit provided by any one of the foregoing embodiments.

Please refer to FIG. 12 in conjunction with FIG. 1, the present application also provides a pulse generating circuit. The pulse generating circuit includes the logic control circuit provided by any one of the embodiments corresponding to FIG. 1 to FIG. 9.

Specifically, the second MOS transistor Q2 and the third MOS transistor Q3 may be connected to the same clock circuit. A first delay inverting circuit T1 is also connected between the output terminal of the clock circuit and the control terminal of the third MOS transistor Q3. The first delay inverting circuit T1 is used to generate the second clock signal CLKND according to the first clock signal CLK, so that the second clock signal CLKND is delayed by a first preset duration relative to the first clock signal CLK, and there are in-phase time and anti-phase time between the first clock signal CLK and the second clock signal CLKND. The second clock signal CLKND is transmitted to the control terminal of the third MOS transistor Q3 through the first delay inverting circuit T1 to control the on/off of the third MOS transistor Q3.

Exemplarily, the first delay inverting circuit T1 may include multiple buffers and an inverter to perform delay processing and inversion processing on the first clock signal CLK to generate the second clock signal CLKND.

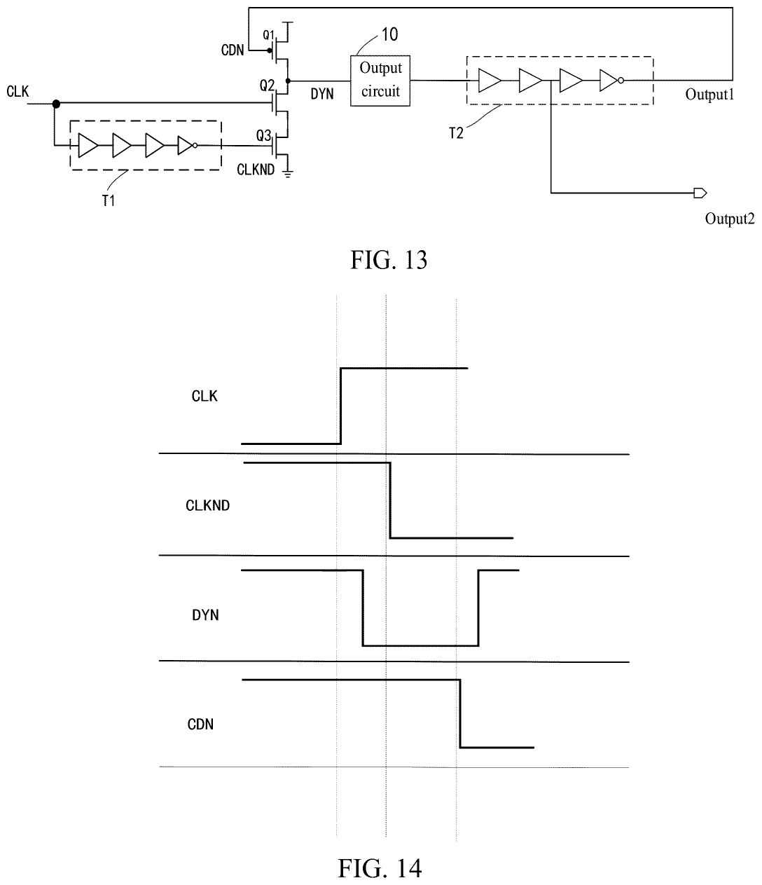

Please refer to FIG. 13 in conjunction with FIG. 12, FIG. 13 is a schematic diagram of a pulse generating circuit provided by another embodiment of the present application. In the pulse generating circuit, the first MOS transistor Q1 is a PMOS transistor, and the second MOS transistor and third MOS transistor Q3 are NMOS transistors. The pulse generating circuit further includes a second delay inverting circuit T2. An input terminal of the second delay inverting circuit T2 is connected to the output terminal of the logic control circuit. An anti-phase output terminal output1 of the second delay inverting circuit T2 is connected to the control terminal of the first MOS transistor Q1, and an in-phase output terminal output2 of the second delay inverting circuit T2 serves as the output terminal of the pulse generating circuit.

It may be understood that the signal output from the anti-phase output terminal output1 of the second delay inverting circuit T2 is inverted with the signal received by the input terminal of the second delay inverting circuit T2. By performing the delay processing and the inversion processing on the pulse signal output from the output terminal of the first inverter M1 in the logic control circuit, the control terminal of the first MOS transistor Q1 is delayed to receive the pulse signal output from the second end of the output circuit 10. It ensures that the level signal of the data node DYN is in-phase with the pulse signal received by the control terminal of the first MOS transistor Q1.

In some other implementations, the first MOS transistor Q1 is a NMOS transistor, and the second MOS transistor and third MOS transistor Q3 are PMOS transistors. Since the level signal of the data node DYN is inverted with the pulse signal received by the control terminal of the first MOS transistor Q1, the inversion processing is not need to perform in the pulse generating circuit, only the delay processing is performed, and the delay circuit is connected between the output terminal of the logic control circuit and the control terminal of the first MOS transistor Q1 to perform the delay processing on the pulse signal output from the second end of the output circuit 10.

Please refer to FIG. 14, FIG. 14 is the timing diagram corresponding to the embodiment in FIG. 13. As shown in the figure, the on/off of the second MOS transistor Q2 and the third MOS transistor Q3 may be controlled by the first clock signal CLK and the second clock signal CLKND, and the on/off of the first MOS transistor Q1 may be controlled by the pulse signal at the second end of the output circuit 10, enabling the pulse generating circuit to generate a periodic pulse signal.

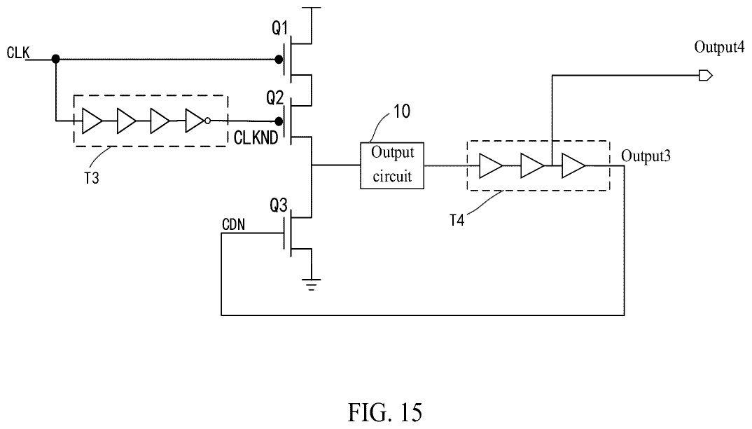

Please refer to FIG. 15 in conjunction with FIG. 10, FIG. 15 is a pulse generating circuit provided by another embodiment of the present application. The pulse generating circuit includes the logic control circuit provided by any one of the embodiments corresponding to FIG. 10 and FIG. 11.

When the first MOS transistor and second MOS transistor Q2 are NMOS transistors and the third MOS transistor Q3 is a PMOS transistor (not shown in the figure), the pulse generating circuit includes a first delay inverting circuit and a second delay inverting circuit. Where one end of the first delay inverting circuit is used to receive the first clock signal CLK, and the other end is connected to the control terminal of the second MOS transistor Q2. The second delay inverting circuit is connected between the second end of the second MOS transistor Q2 and the control terminal of the third MOS transistor Q3. The second delay inverter circuit is used to perform the inversion processing and the delay processing on the pulse signal at the second end of the output circuit 10, so that the pulse signal received by the control terminal of the third MOS transistor Q3 is delayed by a preset duration relative to the pulse signal at the second end of the second MOS transistor Q2. The specific circuit operation steps are the same as those in the previous embodiments and will not be repeated here.

In some other implementations, as shown in FIG. 15, when the first MOS transistor and second MOS transistor Q2 are PMOS transistors and the third MOS transistor Q3 is a NMOS transistor, the pulse generating circuit includes a delay inverter circuit T3 and a delay circuit T4. One end of the delay inverting circuit T3 is used to receive the first clock signal CLK, and the other end is connected to the control terminal of the second MOS transistor Q2. The delay circuit T4 is connected between the second end of the second MOS transistor Q2 and the control terminal of the third MOS transistor Q3. The delay circuit T4 is used to perform the delay processing on the pulse signal output from the second end of the output circuit 10, so that the pulse signal received by the control terminal of the third MOS transistor Q3 is delayed by a preset duration relative to the pulse signal at the second end of the second MOS transistor Q2. The specific circuit operation steps are the same as those in the previous embodiments and will not be repeated here.

It should be understood that the terms used in the specification of the present application are only for the purpose of describing specific embodiments and are not intended to limit the present application. As used in the specification and the accompanying claims, the singular forms of “a”, “an”, and “the” are intended to include the plural forms as well, unless the context clearly indicates otherwise.

It should also be understood that the term “and/or” used in the specification and accompanying claims refers to any and all possible combinations of one or more of the associated listed items, and includes these combinations. It should be noted that, in this article, the terms “comprise”, “include” or any other variations thereof are intended to cover non-exclusive inclusion, so that a process, method, article or system that includes a series of elements includes not only those elements, but also includes other elements not explicitly listed, or also includes elements inherent to such process, method, article or system. Without further limitations, elements defined by the statement “including one . . . ” dos not exclude the existence of additional identical elements in the process, method, article, or system that includes the element.

The serial numbers of the embodiments of the application described above are only for description and do not represent the superiority or inferiority of the embodiments. The above are only the specific implementation manners of the application, but the protection scope of the application is not limited thereto. Any persons skilled in the art within the technical scope disclosed by the application may easily think of various equivalent modifications or replacements, and these modifications or replacements should all be covered within the protection scope of the application. Therefore, the protection scope of the application should be subject to the protection scope of the claims.

What is claimed is:

1. A logic control circuit, comprising: a first MOS transistor, a second MOS transistor, a third MOS transistor, and an output circuit; a first end of the first MOS transistor is connected to a power supply, and a second end of the first MOS transistor is connected to a first end of the second MOS transistor; a second end of the second MOS transistor is connected to a first end of the third MOS transistor, and a second end of the third MOS transistor is grounded;
the second end of the first MOS transistor is further used to connect to a first end of the output circuit, a second end of the output circuit serves as an output terminal of the logic control circuit, and the second end of the output circuit is further used to connect to a control terminal of the first MOS transistor, so as to control on/off of the first MOS transistor through a pulse signal at the second end of the output circuit;
a control terminal of the second MOS transistor is used to receive a first clock signal, and a control terminal of the third MOS transistor is used to receive a second clock signal, a waveform of the second clock signal is the same as that of the first clock signal, and the second clock signal is delayed by a preset duration relative to the first clock signal;
when the first MOS transistor is switched on, the second end of the first MOS transistor is in a high level, and when level of the first clock signal is different from that of the second clock signal, the second MOS transistor or the third MOS transistor is switched off, so as to keep the second end of the first MOS transistor in a high level; and
when the first MOS transistor is switched off, and when the level of the first clock signal is the same as that of the second clock signal, the second MOS transistor and the third MOS transistor are both switched on, so as to set the second end of the first MOS transistor to a low level.

2. The logic control circuit according to claim 1, wherein the output circuit comprises: a fourth MOS transistor, a control terminal of the fourth MOS transistor serves as a control terminal of the output circuit and is used to receive an enable signal, a first end of the fourth MOS transistor is connected to the power supply, and a second end of the fourth MOS transistor is connected to the second end of the first MOS transistor.

3. The logic control circuit according to claim 1, wherein the first MOS transistor is an NMOS transistor, the second and third MOS transistors are PMOS transistors, and the output circuit further comprises: a first inverter, an input terminal of the first inverter is connected to the second end of the first MOS transistor, and the output terminal of the first inverter serves as the second end of the output circuit.

4. The logic control circuit according to claim 2, wherein the first MOS transistor is an NMOS transistor, the second and third MOS transistors are PMOS transistors, and the output circuit further comprises: a first inverter, an input terminal of the first inverter is connected to the second end of the first MOS transistor, and the output terminal of the first inverter serves as the second end of the output circuit.

5. The logic control circuit according to claim 2, wherein the first MOS transistor is an NMOS transistor, the second, third, and fourth MOS transistors are PMOS transistors, and the output circuit further comprises: a NAND gate, a first signal input terminal of the NAND gate is connected to the control terminal of the fourth MOS transistor, a second signal input terminal of the NAND gate is connected to the second end of the fourth MOS transistor, and an output terminal of the NAND gate serves as the second end of the output circuit.

6. The logic control circuit according to claim 3, wherein the logic control circuit further comprises: a fifth MOS transistor, a control terminal of the fifth MOS transistor is connected to the output terminal of the first inverter, a first end of the fifth MOS transistor is used to connect to the power supply, and a second end of the fifth MOS transistor is connected to the input terminal of the first inverter.

7. The logic control circuit according to claim 1, wherein the first MOS transistor is a PMOS transistor, and the second and third MOS transistors are NMOS transistors; the output circuit further comprises: a first inverter, an input terminal of the first inverter is connected to the second end of the first MOS transistor, and an output terminal of the first inverter serves as the second end of the output circuit;
the second end of the output circuit is further used to connect to the control terminal of the first MOS transistor to control the on/off of the first MOS transistor through a pulse signal at the second end of the output circuit, which comprises the control terminal of the first MOS transistor receives an inverting signal of the pulse signal at the second end of the output circuit, so as to control the on/off of the first MOS transistor through the inverting signal of the pulse signal at the second end of the output circuit.

8. The logic control circuit according to claim 2, wherein the first MOS transistor is a PMOS transistor, and the second and third MOS transistors are NMOS transistors; the output circuit further comprises: a first inverter, an input terminal of the first inverter is connected to the second end of the first MOS transistor, and an output terminal of the first inverter serves as the second end of the output circuit;
the second end of the output circuit is further used to connect to the control terminal of the first MOS transistor to control the on/off of the first MOS transistor through a pulse signal at the second end of the output circuit, which comprises the control terminal of the first MOS transistor receives an inverting signal of the pulse signal at the second end of the output circuit, so as to control the on/off of the first MOS transistor through the inverting signal of the pulse signal at the second end of the output circuit.

9. The logic control circuit according to claim 7, wherein the logic control circuit further comprises: a second inverter, a sixth MOS transistor, a seventh MOS transistor and an eighth MOS transistor, wherein the sixth MOS transistor is a PMOS transistor, the seventh and eighth MOS transistors are NMOS transistors; a first end of the sixth MOS transistor is used to connect to the power supply, and a second end of the sixth MOS transistor is connected to a first end of the seventh MOS transistor; a second end of the seventh MOS transistor is connected to a first end of the eighth MOS transistor, and a second end of the eighth MOS transistor is grounded;
control terminals of the sixth MOS transistor and a seventh MOS transistor are both connected to an output terminal of the second inverter, an input terminal of the second inverter is connected to the first end of the output circuit, and the input terminal of the second inverter is further connected to the second end of the sixth MOS transistor, and a control terminal of the eighth MOS transistor is connected to the control terminal of the first MOS transistor.

10. A logic control circuit, comprising: a first MOS transistor, a second MOS transistor, a third MOS transistor, and an output circuit; a first end of the first MOS transistor is used to connect to a power supply, and a second end of the first MOS transistor is connected to a first end of the second MOS transistor; a second end of the second MOS transistor is connected to a first end of the third MOS transistor, and a second end of the third MOS transistor is grounded;
the second end of the second MOS transistor is further connected to a first end of the output circuit, a second end of the output circuit serves as an output terminal of the logic control circuit, and the second end of the output circuit is further connected to a control terminal of the third MOS transistor, so as to control on/off of the third MOS transistor through a pulse signal at the second end of the output circuit;
the first MOS transistor further comprises a control terminal for receiving a first clock signal, and the second MOS transistor further comprises a control terminal for receiving a second clock signal, a waveform of the second clock signal is the same as that of the first clock signal, and the second clock signal is delayed by a preset duration relative to the first clock signal;
when the third MOS transistor is switched off, and when level of the first clock signal is the same as that of the second clock signal, the first MOS transistor and the second MOS transistor are both switched on, so as to set the second end of the first MOS transistor to a high level; and
when the level of the first clock signal is different from that of the second clock signal, the first MOS transistor or the second MOS transistor are switched off, and when the third MOS transistor is switched on, the second end of the first MOS transistor is set to a low level.

11. The logic control circuit according to claim 10, wherein the first and second MOS transistors are NMOS transistors, and the third MOS transistor is a PMOS transistor; the output circuit comprises: an inverter, an input terminal of the inverter is connected to the second end of the second MOS transistor, and an output terminal of the inverter serves as the second end of the output circuit.

12. The logic control circuit according to claim 10, wherein the first and second MOS transistors are PMOS transistors, the third MOS transistor is an NMOS transistor; the output circuit comprises: an inverter, an input terminal of the inverter is connected to the second end of the second MOS transistor, and an output terminal of the inverter serves as the second end of the output circuit;
the second end of the output circuit is further connected to the control terminal of the third MOS transistor to control the on/off of the third MOS transistor through a pulse signal output from the second terminal of the output circuit, which comprises the control terminal of the third MOS transistor is used to receive an inverting signal of the pulse signal at the second end of the output circuit, so as to control the on/off of the third MOS transistor through the inverting signal of the pulse signal at the second end of the output circuit.

13. A flip-flop, comprising:
the logic control circuit according to claim 1.

14. A flip-flop, comprising:
the logic control circuit according to claim 10.

15. A pulse generating circuit, comprising:
the logic control circuit according to claim 1;
a first delay inverting circuit, wherein one end of the first delay inverting circuit is used to receive the first clock signal, and the other end is connected to the control terminal of the third MOS transistor, so as to input the generated second clock signal to the control terminal of the third MOS transistor, delay the second clock signal by a first preset duration relative to the first clock signal.

16. A pulse generating circuit, comprising:
the logic control circuit according to claim 7;
a first delay inverting circuit, wherein one end of the first delay inverting circuit is used to receive the first clock signal, and the other end is connected to the control terminal of the third MOS transistor, so as to input the generated second clock signal to the control terminal of the third MOS transistor, delay the second clock signal by a first preset duration relative to the first clock signal.

17. The pulse generating circuit according to claim 15, wherein the pulse generating circuit further comprises: a delay circuit, the delay circuit is connected between the output terminal of the logic control circuit and the control terminal of the first MOS transistor, and an output terminal of the delay circuit further serves as an output terminal of the pulse generating circuit; the delay circuit is used to perform delay processing on the pulse signal at the second end of the output circuit, so that the pulse signal received by the control terminal of the first MOS transistor is delayed by a second preset duration relative to the pulse signal at the second end of the output circuit.

18. The pulse generating circuit according to claim 16, wherein the pulse generating circuit further comprises: a second delay inverting circuit, an input terminal of the second delay inverting circuit is connected to the output terminal of the logic control circuit, and an anti-phase output terminal of the second delay inverting circuit is connected to the control terminal of the first MOS transistor; an in-phase output terminal of the second delay inverting circuit serves as the output terminal of the pulse generating circuit, the second delay inverting circuit is used to perform delay processing and inversion processing on the pulse signal output from the second end of the output circuit, so that the pulse signal received by the control terminal of the first MOS transistor is delayed by a second preset duration relative to the pulse signal at the second end of the output circuit.

19. A pulse generating circuit, comprising:
the logic control circuit according to claim 10;
a first delay inverting circuit, wherein one end of the first delay inverting circuit is used to receive the first clock signal, and the other end is connected to the control terminal of the second MOS transistor;
a second delay inverting circuit, the second delay inverting circuit is connected between the second end of the output circuit and the control terminal of the third MOS transistor; the second delay inverting circuit is used to perform inversion processing and delay processing on the pulse signal at the second end of the output circuit, so that the pulse signal received by the control terminal of the third MOS transistor is delayed by a preset duration relative to the pulse signal at the second end of the second MOS transistor.

20. A pulse generating circuit, comprising:
the logic control circuit according to claim 10;
a delay inverting circuit, wherein one end of the delay inverting circuit is used to receive the first clock signal, and the other end is connected to the control terminal of the second MOS transistor;
a delay circuit, wherein the delay circuit is connected between the second end of the output circuit and the control terminal of the third MOS transistor; the delay circuit is used to perform delay processing on the pulse signal output from the second end of the output circuit, so that the pulse signal received by the control terminal of the third MOS transistor is delayed by a preset duration relative to the pulse signal at the second end of the second MOS transistor.
